(19) United States
(12) Patent Application Publication
(10) Pub. No.: US 2015/0028457 A1
(43) Pub. Date: Jan. 29, 2015

(54) EPITAXIAL SUBSTRATE, SEMICONDUCTOR DEVICE, AND METHOD FOR MANUFACTURING SEMICONDUCTOR DEVICE

(71) Applicant: SHIN-ETSU HANDOTAI CO., LTD., Tokyo (JP)

(72) Inventors: Hiroshi Shikauchi, Niiza (JP); Hirokazu Goto, Minato-ku (JP); Ken Sato, Miyoshi-machi (JP); Masaru Shinomiya, Annaka (JP); Keitaro Tsuchiya, Takasaki (JP); Kazunori Hagimoto, Takasaki (JP)

(21) Appl. No.: 14/376,475

(22) PCT Filed: Feb. 14, 2013
(86) PCT No.: PCT/JP2013/000800

§ 371 Date: Aug. 4, 2014

(30) Foreign Application Priority Data
Feb. 20, 2012 (JP) 2012-033655

(51) Int. Cl. H01L 21/322; H01L 29/34; H01L 29/20

(52) U.S. Cl. CPC H01L 21/3228; H01L 29/2003; H01L 29/34
USPC 257/629; 438/471

(57) ABSTRACT

The present invention includes: a silicon-based substrate; and an epitaxial growth layer that has a configuration in which first and second nitride semiconductor layers having different lattice constants and thermal expansion coefficients are alternately laminated, and is arranged on the silicon-based substrate so that a film thickness thereof is gradually reduced at an outer edge portion. As a result, there are provided an epitaxial substrate and a semiconductor device in which generation of cracks at the outer edge portion is suppressed, and a method for manufacturing the semiconductor device.

### TECHNICAL FIELD

The present invention relates to an epitaxial substrate having an epitaxial growth layer, a semiconductor device, and a method for manufacturing a semiconductor device.

### BACKGROUND ART

In a semiconductor device having a nitride semiconductor layer, it is often the case that a nitride semiconductor layer is formed on an inexpensive silicon-based substrate such as silicon and silicon carbide. For example, a nitride semiconductor layer that functions as a functional layer in a semiconductor device, e.g., an active layer of a light-emitting diode (LED) or a channel layer of a high electron mobility transistor (HEMT) is formed on a silicon-based substrate. However, lattice constants of the silicon-based substrate and the nitride semiconductor layer are greatly different from each other. Therefore, for example, a configuration in which a buffer layer is arranged between the silicon-based substrate and the functional layer is adopted.

As an epitaxial growth layer such as a buffer layer and a functional layer, a configuration in which a plurality of heterostructures of AlₓGa₁₋ₓN/Al_{y}Ga_{1-y}N(x>y) are laminated, e.g., a configuration in which aluminum nitride (AlN) layers and gallium nitride (GaN) layers are alternately laminated is generally used. It is to be noted that an AlN initial layer thicker than the buffer layer may be further arranged between the buffer layer and the silicon-based substrate.

Since the epitaxial growth layer has a heterostructure like AlN/GaN, many cracks are apt to be made from an outer edge portion due to a difference in lattice constant or a difference in thermal expansion coefficient.

Further, in an epitaxial substrate having an epitaxial growth layer made of a nitride semiconductor arranged on a silicon-based substrate, a film thickness of the epitaxial growth layer is large at an outer edge portion, and a “crown” of the epitaxial growth layer or the silicon-based substrate is generated. Conditions such as a thickness of each layer in a semiconductor device are selected so that a warp of the silicon-based substrate and stress of the epitaxial growth layer can be optimum at a central portion that is used as the semiconductor device. Therefore, when the crown is generated, the stress produced in the epitaxial growth layer and the warp of the substrate become unbalanced, the epitaxial growth layer is affected, and cracks and the like having a hexagonal pattern are generated in the epitaxial growth layer near the outer edge portion. To avoid generation of the crown, there has been suggested, e.g., a method for chamfering the outer edge portion of the silicon-based substrate and growing the epitaxial growth layer on the silicon-based substrate (see, e.g., Patent Literature 1).

### CITATION LIST

### Patent Literature

Patent Literature 1: Japanese Unexamined Patent Application Publication No. Sho 59-227117

### SUMMARY OF INVENTION

### Technical Problem

In general, under the existing circumstances, cracks are present in a region that is approximately several mm from an outer edge portion on an epitaxial substrate which is called “crack-free” due to generation of the crown. There is concern that the cracks are expanded in a device manufacturing process or cause delamination of an epitaxial growth layer to contaminate a manufacturing line. Therefore, a completely crack-free epitaxial substrate has been demanded.

To meet the demand, it is an object of the present invention to provide an epitaxial substrate and a semiconductor device in which generation of cracks at an outer edge portion is suppressed, and a method for manufacture such a semiconductor device.

### Solution to Problem

According to one aspect of the present invention, there is provided an epitaxial substrate comprising: (a) a silicon-based substrate; and (b) an epitaxial growth layer that has a configuration in which first and second nitride semiconductor layers having different lattice constants and thermal expansion coefficients are alternately laminated, and is arranged on the silicon-based substrate so that a film thickness thereof is gradually reduced at an outer edge portion.

According to another aspect of the present invention, there is provided a semiconductor device comprising: (a) a silicon-based substrate; (b) an epitaxial growth layer that has a configuration in which first and second nitride semiconductor layers having different lattice constants and different thermal expansion coefficients are alternately laminated, and is arranged on the silicon-based substrate so that a film thickness is gradually reduced at an outer edge portion thereof and a film thickness reduction rate increases toward an outer side; and (c) a functional layer which is arranged on the epitaxial growth layer and made of a nitride semiconductor.

According to still another aspect of the present invention, there is provided a method for manufacturing a semiconductor device comprising: (a) a step of preparing an epitaxial substrate comprising a silicon-based substrate and an epitaxial growth layer that has a configuration in which first and second nitride semiconductor layers having different lattice constants and different thermal expansion coefficients are alternately laminated and is arranged on the silicon-based substrate so that a film thickness is gradually reduced at an outer edge portion; (b) a step of forming a functional layer made of a nitride semiconductor on the epitaxial growth layer; and (c) a step of performing dicing to provide each unit.

### Advantageous Effects of Invention

According to the present invention, it is possible to provide the epitaxial substrate and the semiconductor device in which generation of cracks at the outer edge portion is suppressed, and the method for manufacturing such a semiconductor device.

### BRIEF DESCRIPTION OF DRAWINGS

FIGS. 1 are schematic cross-sectional views each showing a configuration of an epitaxial substrate according to a first embodiment of the present invention, where FIG. 1(a) is a general view, and FIG. 1(b) and FIG. 1(c) are enlarged views of an end portion;

FIG. 2 is a schematic cross-sectional view showing a configuration of an outer edge portion of an epitaxial substrate according to a comparative example;

FIG. 3 is a surface picture of the outer edge portion of the epitaxial growth layer according to the comparative example;

FIG. 4 is a graph in which thermal expansion coefficients of respective materials are compared;

FIG. 5 is a schematic cross-sectional view showing a configuration of an outer edge portion of an epitaxial substrate according to a first embodiment of the present invention;

FIG. 6 is a surface picture of an outer edge portion of an epitaxial growth layer according to the first embodiment of the present invention;

FIG. 7 is a graph showing an example of a film thickness distribution of the outer edge portion of the epitaxial growth layer on the epitaxial substrate according to the first embodiment of the present invention;

FIG. 8 is a table showing an example of a film thickness distribution of the outer edge portion of the epitaxial growth layer on the epitaxial substrate according to the first embodiment of the present invention;

FIGS. 9 are schematic views for explaining an example of a method for manufacturing an epitaxial substrate according to the first embodiment of the present invention, where FIG. 9(a) is a plan view and FIG. 9(b) is a cross-sectional view;

FIG. 10 is a schematic cross-sectional view showing a structural example of a semiconductor device using an epitaxial substrate according to the first embodiment of the present invention;

FIG. 11 is a schematic cross-sectional view showing a structural example corresponding to one unit of the semiconductor device depicted in FIG. 10;

FIG. 12 is a schematic cross-sectional view showing another structural example of the semiconductor device using the epitaxial substrate according to the first embodiment of the present invention;

FIG. 13 is a schematic cross-sectional view showing a structural example corresponding to one unit of the semiconductor device depicted in FIG. 12;

FIG. 14 is a schematic cross-sectional view showing a configuration of an epitaxial substrate according to a second embodiment of the present invention; and

FIG. 15 is a schematic cross-sectional view showing a configuration of an epitaxial substrate according to a third embodiment of the present invention.

### DESCRIPTION OF EMBODIMENTS

First to third embodiments according to the present invention will now be described hereinafter with reference to the drawings. In the following description of the drawings, like or similar reference signs denote like or similar parts. However, the drawings are schematic, and it should be noted that a relationship between a thickness and a planar size, a ratio of a length of each portion, and others are different from actual values. Therefore, each specific dimension should be determined while taking the following explanation into consideration. Furthermore, it is needless to say that the drawings include a relationship between dimensions and portions having different ratios.

Furthermore, the following first to third embodiments illustrate a device or a method for embodying the technical concept of the present invention, and the technical concept of the present invention do not specify a shape, a configuration, arrangement, and others of a constituent component as the following. Embodiments according to the present invention can be modified in many ways within the scope of claims.

### First Embodiment

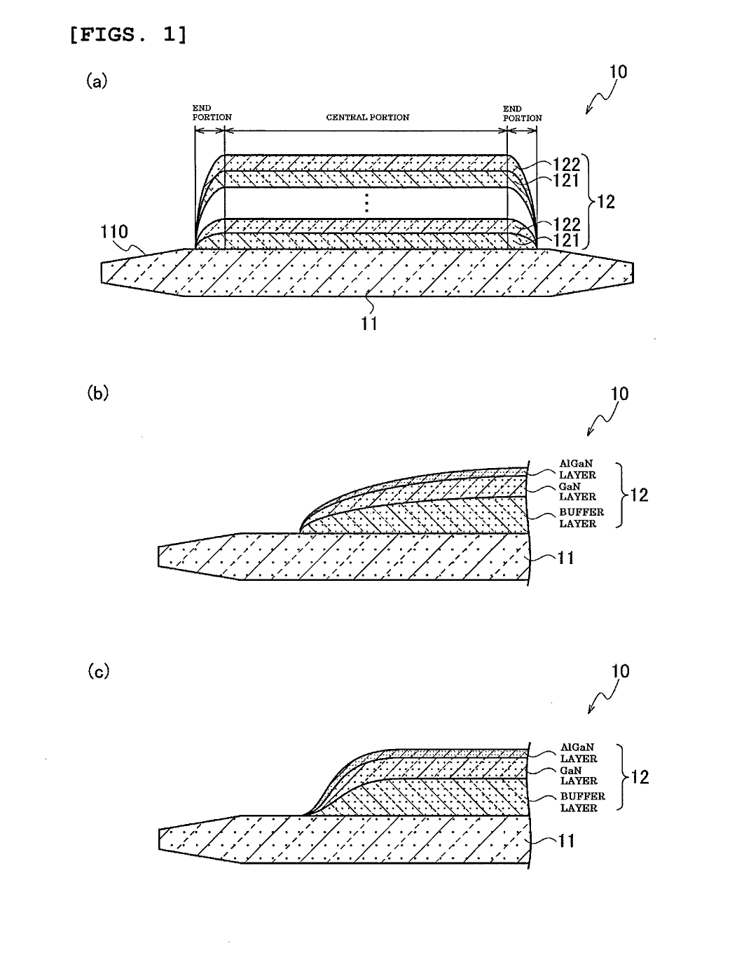

As shown in FIG. 1(a), an epitaxial substrate 10 according to a first embodiment of the present invention includes a silicon-based substrate 11 and an epitaxial growth layer 12 arranged on the silicon-based substrate 11 so that a film thickness is gradually reduced at an outer edge portion. That is, in the epitaxial growth layer 12, a shape of an outer edge of a cutting plane along a film thickness direction of the outer edge portion (an end portion) is a convex arc shape as shown in FIG. 1(a). Moreover, the epitaxial growth layer 12 has a buffer layer configuration in which first nitride semiconductor layers 121 and second nitride semiconductor layers 122 having lattice constants and thermal expansion coefficients different from each other are alternately laminated.

Additionally, as shown in FIG. 1(b) and FIG. 1(c), when a functional layer made of a nitride semiconductor is formed on the epitaxial substrate 10 depicted in FIG. 1(a), a semiconductor device is manufactured. For example, it is possible to realize a semiconductor device in which the epitaxial growth layer 12 is formed as a buffer layer and a functional layer is formed thereon. It is to be noted that the functional layer made of a nitride semiconductor formed on the buffer layer to manufacture the semiconductor device is also included in the epitaxial growth layer 12.

An end portion of the epitaxial growth layer 12 has a film thickness that is gradually reduced so that a film thickness reduction rate increases toward the outer side as shown in FIG. 1(b). Alternatively, as shown in FIG. 1(c), the end portion of the epitaxial growth layer 12 is gradually thinned. It is to be noted that each of FIG. 1(b) and FIG. 1(c) shows an example that the epitaxial growth layer 12 has the configuration in which functional layers, i.e., a GaN layer and an AlGaN layer are laminated on the buffer layer. A ratio of film thicknesses of the respective layers constituting the epitaxial growth layer 12 is substantially the same at a position near the end portion and a central portion. It is to be noted the “central portion” is a portion on the inner side of the end portion of the epitaxial growth layer 12, the portion being used as a semiconductor device.

In the epitaxial substrate shown in FIG. 1(a), the end portion of the epitaxial growth layer 12 is provided on the inner side of the end portion of the silicon-based substrate 11, and film thicknesses of the first and second nitride semiconductor layers 121 and 122 are each gradually increased from the end portion toward the central portion. That is, the epitaxial growth layer 12 is arranged on a central region of a main surface 110 of the silicon-based substrate 11, and it is not arranged on an outer peripheral region of the main surface 110 that surrounds the central region. Therefore, the main surface of the silicon-based substrate 11 is exposed in the outer peripheral region. Each of the first and second nitride semiconductor layers 121 and 122 is, e.g., a nitride semiconductor made of AlₓIn_{y}Ga_{1-x-y}N (0≦x1, 0≦y≦1, 0≦1-x-y≦1).

The silicon-based substrate 11 is, e.g., a silicon (Si) substrate or a silicon carbide (SiC) substrate. As shown in FIG. 1(a), the outer edge portion of the silicon-based substrate 11 is chambered so that the film thickness is reduced as getting closer to the end portion.

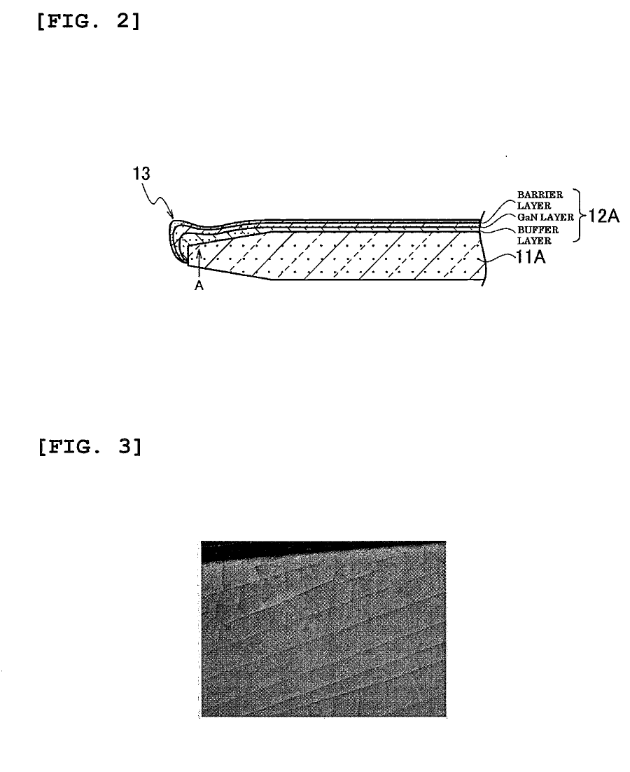

In general, when an epitaxial film made of a nitride semiconductor has been grown on the silicon-based substrate, a film thickness of an epitaxial growth layer 12A increases at an outer edge portion of the silicon-based substrate 11A and a crown 13 is generated as shown in FIG. 2. A comparative example shown in FIG. 2 has a configuration in which a buffer layer, a GaN layer, and an AlGaN barrier layer are laminated as the epitaxial growth layer 12A. As described above, cracks are produced in the epitaxial substrate due to generation of the crown 13. FIG. 3 shows a surface picture of the outer edge portion of the epitaxial growth layer 12A denoted by reference sign A in FIG. 2. As shown in FIG. 3, streaky cracks are produced in the epitaxial growth layer 12A.

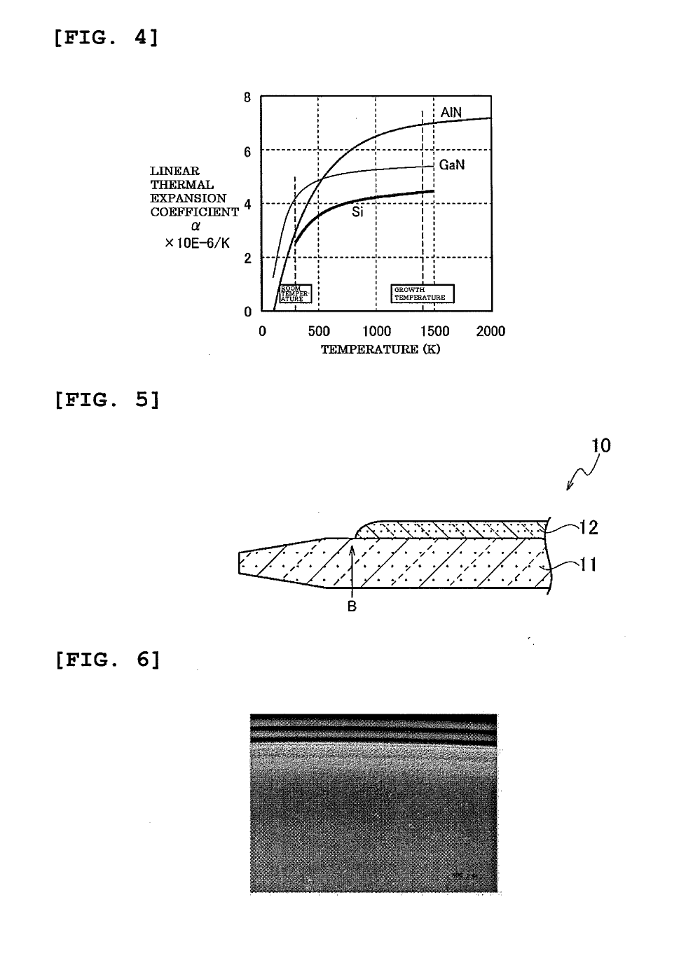

FIG. 4 shows a graph in which thermal expansion coefficients of respective materials are compared with each other. FIG. 4 shows a relationship between a temperature and a thermal expansion coefficient α of each semiconductor material. At 1000 K or more, a relationship of thermal expansion coefficients of respective materials is Si<GaN<AlN, and a relationship of lattice constants of the same is AlN (a-axis)<GaN (a-axis)<Si((111) plane). Since Si, AlN, and GaN have differences in lattice constant or thermal expansion coefficient and others, such cracks as shown in FIG. 3 are apt to be produced when a temperature of the silicon-based substrate is set to 1000 K or more and lamination is carried out.

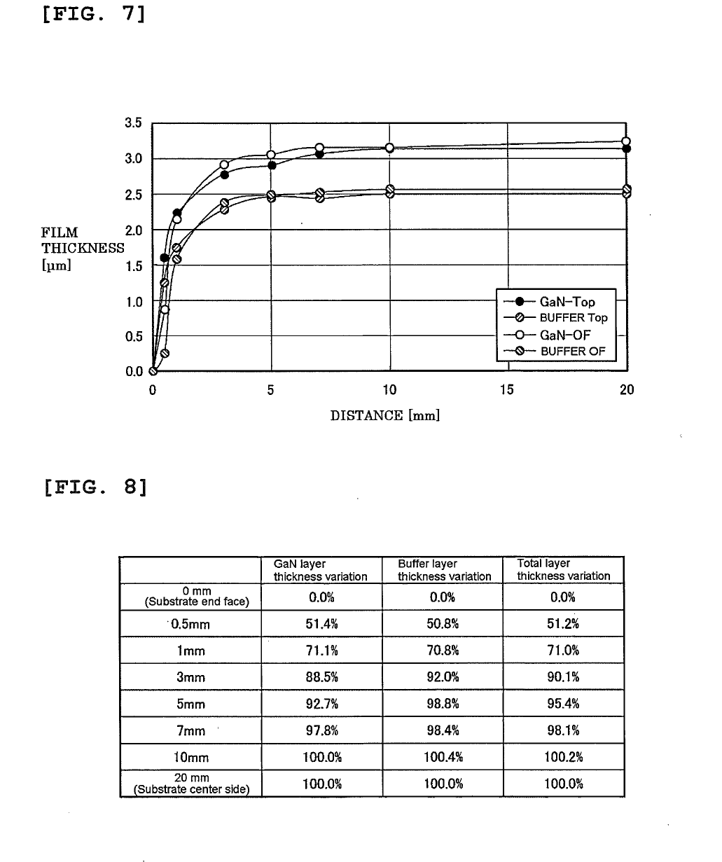

To compare with the comparative example shown in FIG. 2, a state of the outer edge portion of the epitaxial substrate 10 depicted in FIG. 1(a) will now be described hereinafter. FIG. 6 shows a surface picture of the outer edge portion of the epitaxial growth layer 12 denoted by reference sign B in FIG. 5. As shown in FIG. 6, no crack is generated in the silicon-based substrate 11. A film thickness of the epitaxial growth layer 12 in the central region of the silicon-based substrate 11 in this case is 6 μm. That is, when the epitaxial growth layer 12 having the film thickness of 6 μm was formed, it was confirmed that no crack was generated in the silicon-based substrate 11 at the outer edge portion of the epitaxial growth layer 12.

As described above, when the epitaxial growth layer 12 is formed so that the film thickness is gradually reduced at the outer edge portion, the crown of the epitaxial growth layer 12 is not produced at the outer edge portion of the silicon-based substrate 11. As a result, generation of the cracks in the silicon-based substrate 11 or delamination of the epitaxial growth layer 12 can be suppressed.

FIG. 7 shows an example of a film thickness distribution of the epitaxial growth layer 12 at the outer edge portion. An axis of ordinate in FIG. 7 represents a film thickness of the epitaxial growth layer 12, and an axis of abscissa in the same represents a distance from an end of the outer edge portion of the epitaxial growth layer 12 to the central region along the main surface 110 of the silicon-based substrate 11. It is to be noted that a buffer layer and a GaN layer were laminated as the epitaxial growth layer 12 on the silicon-based substrate 11. In FIG. 7, “GaN-OF” and “BUFFER-OF” represent film thicknesses of the GaN layer and the buffer layer on a side close to an orientation flat of the substrate (which will be referred to as an “OF side” hereinafter), and “GaN-Top” and “BUFFER-Top” represent film thicknesses of the GaN layer and the buffer layer on a side far from the orientation flat of the substrate (which will be referred to as a “Top side” hereinafter). FIG. 8 shows variations of film thicknesses of the buffer layer and the GaN layer and variations of a total film thickness of the buffer layer and the GaN layer on the Top side.

As described above, the film thickness of the epitaxial growth layer 12 is gradually reduced toward the outer side, and a film thickness reduction rate increases toward the outer side. For example, assuming that the film thickness of the epitaxial growth layer 12 in the central region that is 20 mm from the end of the outer edge portion is 100%, the epitaxial growth layer 12 is formed in such a manner that the film thickness is approximately 90% in a region that is 3 mm apart from the end of the outer edge portion, approximately 70% in a region that is 1 mm apart from the end of the outer edge portion, and approximately 50% in a region that is 0.5 mm apart from the end of the outer edge portion.

When the film thickness of the epitaxial growth layer 12 increases, cracks are apt to be produced in the epitaxial substrate 10. Therefore, when the film thickness of the epitaxial growth layer 12 in the central portion is, e.g., 5 μm or more, an effect of reducing generation of cracks becomes prominent by gradually decreasing the film thickness of the epitaxial growth layer 12 at the outer edge portion.

Moreover, as a diameter of the epitaxial growth layer 12 increases, the cracks are apt to be generated in the outer edge portion. Therefore, for example, when the diameter of the epitaxial substrate 10 is 125 mm or more, a crack generation suppressing effect can be enhanced by gradually reducing the film thickness of the epitaxial growth layer 12.

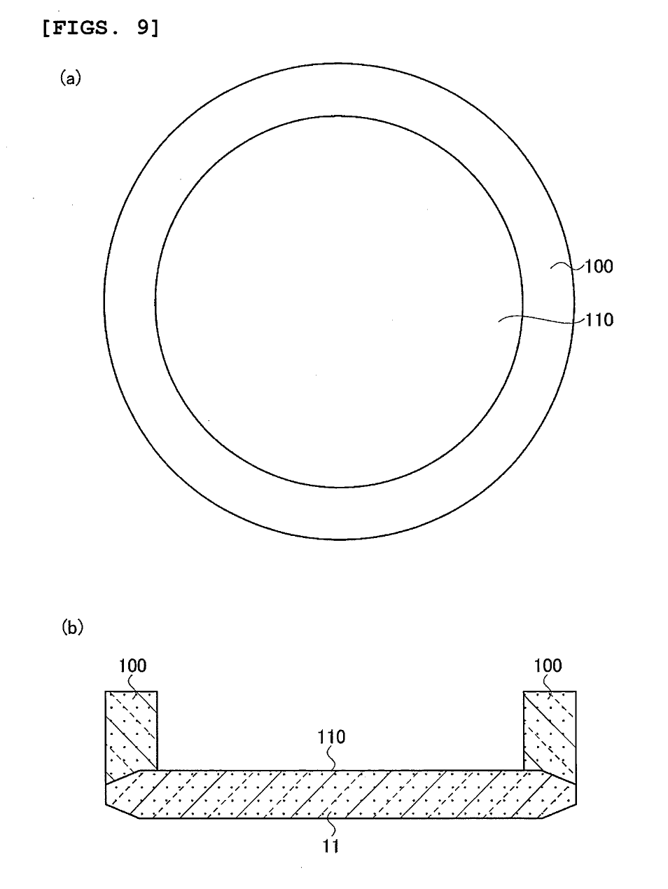

The epitaxial substrate 10 shown in FIG. 1(a) can be manufactured by, e.g., a manufacturing method depicted in FIG. 9(a) and FIG. 9(b). That is, an annular ring 100 is arranged on an outer peripheral region of the main surface 110 of the silicon-based substrate 11 along the outer periphery. The ring 100 is made of, e.g., silicon. The epitaxial growth layer 12 is formed on the main surface 110 of the silicon-based substrate 11 having the ring 100 arranged thereon by using an epitaxial growth method such as a metal organic chemical vapor deposition (MOCVD) method. Then, when the ring 100 is removed from the silicon-based substrate 11, the epitaxial substrate 10 shown in FIG. 1(a) is brought to completion. The epitaxial growth layer 12 is not formed on the outer peripheral region of the silicon-based substrate 11 where the ring 100 was arranged during epitaxial growth, and a surface of the silicon-based substrate 11 is exposed.

An optimum configuration of the epitaxial growth layer 12 as the buffer layer is a configuration that the AlN layers and the GaN layers are alternately laminated, and the epitaxial growth layer 12 is formed on the silicon-based substrate 11 set to 900° C. or a higher temperature, e.g., 1350° C.

As described above, according to the epitaxial substrate 10 of the first embodiment of the present invention, the crown can be prevented from being generated when the film thickness of the epitaxial growth layer 12 increases at the outer edge portion, and production of cracks or delamination of the epitaxial film can be suppressed. Since the epitaxial substrate 10 is a crack-free substrate in which the cracks are not produced as described above, it is possible to suppress a phenomenon (meltback etching) that the cracks are produced during the epitaxial growth and a starting material gas and the silicon-based substrate react with each other.

Additionally, since the film thickness of the epitaxial growth layer 12 is small at the outer edge portion in the epitaxial substrate 10, stress produced from the end portion due to a difference between thermal expansion coefficients of the silicon-based substrate 11 and both the first nitride semiconductor layer 121 and the second nitride semiconductor layer 122 constituting the epitaxial growth layer 12 is weak, and a warp of the epitaxial substrate 10 can be easily controlled. For example, in case of comparing with the comparative example shown in FIG. 2, if the film thickness of the epitaxial growth layer 12 is unchanged, an amount of warp that is dependent on the stress is small. Further, when the amount of warp is unchanged, the epitaxial growth layer 12 can be thickly grown.

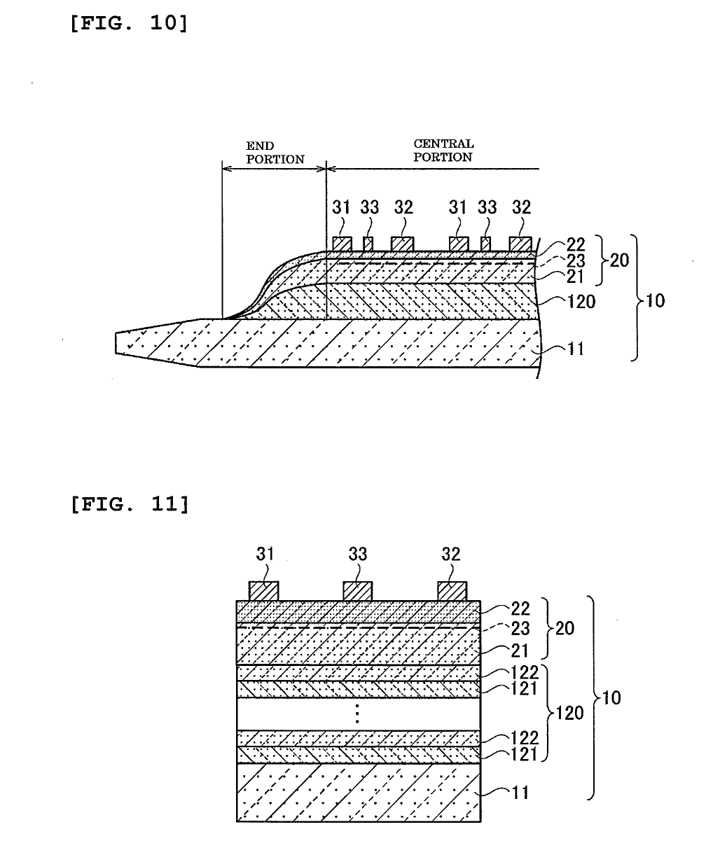

FIG. 10 shows an example where an HEMT (High Electron Mobility Transistor) is formed with the use of the epitaxial substrate 10. That is, a semiconductor device shown in FIG. 10 has a functional layer 20 having a configuration in which a carrier supply layer 22 and a carrier transit layer 21 that forms a heterojunction with the carrier supply layer 22 are laminated. A heterojunction interface is formed on an interface between the carrier transit layer 21 and the carrier supply layer 22 that are made of nitride semiconductors having different band gap energies, and a two-dimensional carrier gas layer 23 as a current path (a channel) is formed in the carrier transit layer 21 near the heterojunction interface.

A buffer layer 120 of the semiconductor device shown in FIG. 10 is a multilayer structure buffer in which, for example, a first sub-layer made of AlN and a second sub-layer made of GaN are alternately laminated.

The carrier transit layer 21 arranged on the buffer layer 120 is formed by, e.g., epitaxially growing non-doped GaN having no impurity added thereto by the MOCVD method or the like. Non-doping means that no impurity is added intentionally.

Here, it is preferable for a ratio of a change of a thickness of the buffer layer 120 in the end portion relative to the same in the central portion to be substantially equal to a ratio of a change of the thickness of the carrier transit layer 21 in the end portion relative to the same in the central portion within ±5%, and also preferable for the thickness of each of the buffer layer 120 and the carrier transit layer 21 in the end portion to change at the same ratio. It is to be noted that the ratio of change of the carrier transit layer 21 may be higher than the ratio of change of the buffer layer 120.

The carrier supply layer 22 arranged on the carrier transit layer 21 is made of a nitride semiconductor having a higher band gap than the carrier transit layer 21 and a smaller lattice constant than the carrier transit layer 21. As the carrier supply layer 22, non-doped AlₓGa₁₋ₓN can be adopted.

The carrier supply layer 22 is formed on the carrier transit layer 21 by epitaxial growth based on the MOCVD method or the like. Since the carrier supply layer 22 and the carrier transit layer 21 have different lattice constants, piezoelectric polarization occurs due to lattice distortion. This piezoelectric polarization and spontaneous polarization of a crystal in the carrier supply layer 22 cause high-density carriers in the carrier transit layer 21 near the heterojunction, and the two-dimensional carrier gas layer 23 as the current path (the channel) is formed.

As shown in FIG. 10, source electrodes 31, drain electrodes 32, and gate electrodes 33 are formed on the functional layer 20. The source electrodes 31 and the drain electrodes 32 are made of metals that can form low-resistance contact (ohmic contact) with the functional layer 20. For example, aluminum (Al) or titanium (Ti) can be adopted for the source electrodes 31 and the drain electrodes 32. Alternatively, the source electrodes 31 and the drain electrodes 32 are formed as laminated bodies of Ti and Al. For example, nickel gold (NiAu) or the like can be adopted for the gate electrode 33 arranged between the source electrode 31 and the drain electrode 32. The source electrodes 31, the drain electrodes 32, and the gate electrodes 33 are formed only in the central portion of the epitaxial growth layer.

Then, as shown in FIG. 11, dicing is carried out to provide each unit of the semiconductor device, thereby manufacturing a chip.

Although the example where the semiconductor device using the epitaxial substrate 10 is the HEMT has been described above, a transistor having a different configuration such as a field effect transistor (FET) may be formed by using the epitaxial substrate 10.

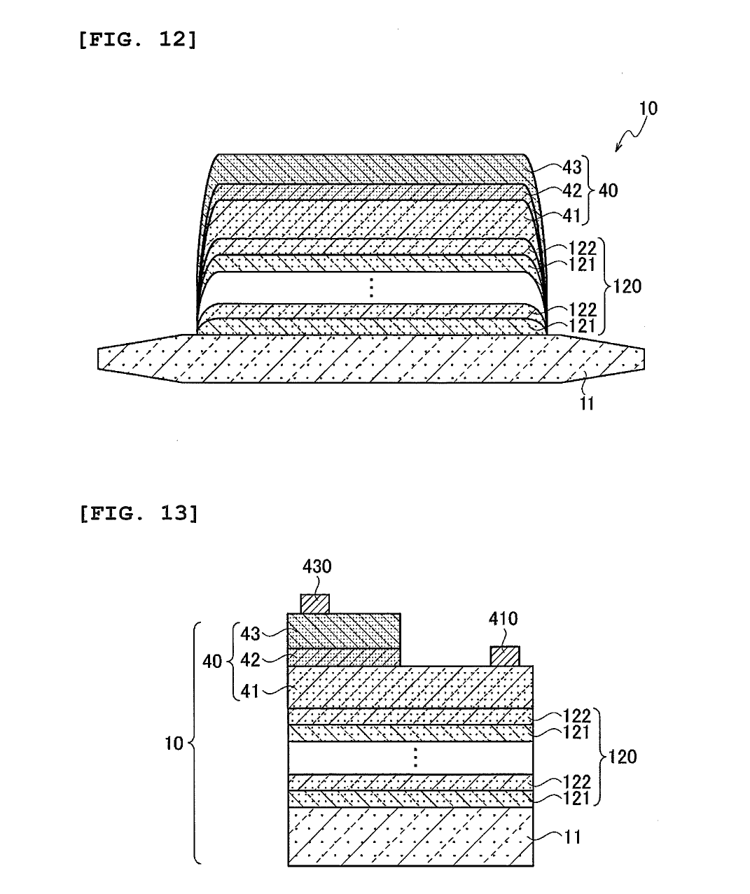

Further, a light-emitting device such as an LED may be manufactured by using the epitaxial substrate 10. A light-emitting device shown in FIG. 12 is an example where a functional layer 40 having a double heterojunction structure in which an n-type clad layer 41, an active layer 42, and a p-type clad layer 43 are laminated is arranged on a buffer layer 120.

The n-type clad layer 41 is, e.g., a GaN film doped with an n-type impurity. As shown in FIG. 13, an n-side electrode 410 is connected to the n-type clad layer 41, and electrons are supplied to the n-side electrode 410 from a negative power supply provided outside the light-emitting device. As a result, the electrons are supplied from the n-type clad layer 41 to the active layer 42.

The p-type clad layer 43 is, e.g., an AlGaN film doped with a p-type impurity doped. A p-side electrode 430 is connected to the p-type clad layer 43, and holes are supplied to the p-side electrode 430 from a positive power supply provided outside the light-emitting device. As a result, the holes are supplied to the active layer 42 from the p-type clad layer 43.

The active layer 42 is, e.g., a non-doped InGaN film. Although FIG. 12 and FIG. 13 show the active layer 42 as a single layer, the active layer 42 has a multiquantum well (MQW) structure in which a barrier layer and a well layer that has a smaller band gap than the barrier layer are alternately arranged. However, the active layer 42 can be constituted of one layer. Furthermore, the active layer 42 may be doped with a p-type or n-type conductive impurity. The electrons supplied from the n-type clad layer 41 and the holes supplied from the p-type clad layer 43 are recombined in the active layer 42, whereby light is generated.

As described above, semiconductor devices having various kinds of functional layers can be realized by using the epitaxial substrate 10 shown in FIG. 1(a).

### Second Embodiment

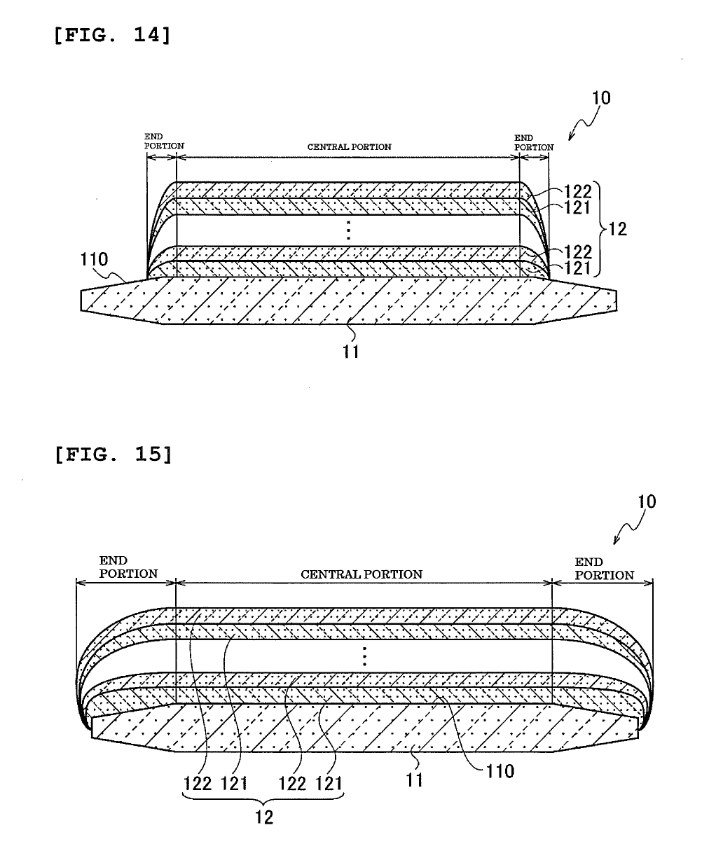

In an epitaxial substrate 10 according to a second embodiment of the present invention, as shown in FIG. 14, an end portion of an epitaxial growth layer 12 is placed on a chamfered region of an end portion of a silicon-based substrate 11. Other points are the same as those in the first embodiment shown in FIG. 1(a).

In the epitaxial substrate 10 shown in FIG. 14, at an angular portion on the inner side of the silicon-based substrate 11 formed by chamfering and the vicinity thereof, a film thickness of each layer in the epitaxial growth layer 12 is slightly larger than that at a periphery thereof due to an influence of a shape of the silicon-based substrate 11 which is a substrate of the epitaxial growth layer 12. However, the film thickness of each layer in the epitaxial growth layer 12 is gradually reduced from the upper side of the angular portion formed by chamfering toward the end portion. In addition, it is also preferable for the film thickness of each layer in the epitaxial growth layer 12 to be gradually reduced toward the end portion on the inner side of the angular portion formed by chamfering, i.e., a non-chamfered region of the silicon-based substrate 11.

Other points are substantially the same as those in the first embodiment, and overlapping descriptions will be omitted.

### Third Embodiment

In an epitaxial substrate 10 according to a third embodiment of the present invention, as shown in FIG. 15, an end portion of an epitaxial growth layer 12 extends to the outer side of an end portion of a silicon-based substrate 11. Other points are the same as those in the first embodiment shown in FIG. 1(a).

In the epitaxial substrate 10 shown in FIG. 15, at the end portion of the silicon-based substrate 11 and an angular portion formed by chamfering and in the vicinity of these portions, a film thickness of each layer in the epitaxial growth layer 12 is slightly larger than that at the periphery thereof due to an influence of a shape of the silicon-based substrate 11 which is a substrate of the epitaxial growth layer 12. However, a thickness of the epitaxial growth layer 12 is gradually reduced toward the end portion of the epitaxial growth layer 12 from the upper side of the end portion of the silicon-based substrate 11 and the angular portion. In addition, it is also preferable for the film thickness of each layer in the epitaxial growth layer 12 to be gradually reduced toward the end portion on the inner side of the angular portion formed by chamfering, i.e., a non-chamfered region of the silicon-based substrate 11.

Other points are substantially the same as those of the first embodiment, and overlapping descriptions will be omitted.

### Other Embodiments

Although the present invention has been described above based on the first to third embodiments, it should not be understood that the statement and the drawings forming part of this disclosure restrict the present invention. Various alternative embodiments, examples, and operation technologies will become obvious to persons skilled in the art from this disclosure.

For instance, the example using the silicon-based substrate 11 having the chamfered end portion has been described in the embodiment shown in FIG. 1(a), but the end portion of the silicon-based substrate 11 does not have to be chamfered.

As described above, it is needless to say that the present invention includes various embodiments and others that are not described herein. Therefore, the technical scope of the present invention is determined solely by matters used to specify the invention concerning appropriate claims from the above description.

1-5. (canceled)

6. An epitaxial substrate comprising:
a silicon-based substrate; and
an epitaxial growth layer that has a configuration in which first and second nitride semiconductor layers having different lattice constants and thermal expansion coefficients are alternately laminated, and is arranged on the silicon-based substrate so that a film thickness thereof is gradually reduced at an outer edge portion.

7. The epitaxial substrate according to claim 6,
wherein an end portion of the epitaxial growth layer is provided on an inner side of an end portion of the silicon-based substrate, and film thicknesses of the first and second nitride semiconductor layers are each formed to gradually increase from the end portion toward a central portion.

8. The epitaxial substrate according to claim 6,
wherein the outer edge portion of the silicon-based substrate is chamfered so that the film thickness is gradually reduced toward the end portion, and the end portion of the epitaxial growth layer is placed on a chamfered region of the silicon-based substrate.

9. The epitaxial substrate according to claim 7,
wherein the outer edge portion of the silicon-based substrate is chamfered so that the film thickness is gradually reduced toward the end portion, and the end portion of the epitaxial growth layer is placed on a chamfered region of the silicon-based substrate.

10. A semiconductor device comprising:
the epitaxial substrate according to claim 6; and
a functional layer made of a nitride semiconductor arranged on the epitaxial growth layer.

11. A semiconductor device comprising:
the epitaxial substrate according to claim 7; and
a functional layer made of a nitride semiconductor arranged on the epitaxial growth layer.

12. A semiconductor device comprising:
the epitaxial substrate according to claim 8; and
a functional layer made of a nitride semiconductor arranged on the epitaxial growth layer.

13. A semiconductor device comprising:
the epitaxial substrate according to claim 9; and
a functional layer made of a nitride semiconductor arranged on the epitaxial growth layer.

14. A method for manufacturing a semiconductor device comprising:
a step of preparing the epitaxial substrate according to claim 6;
a step of forming a functional layer made of a nitride semiconductor on the epitaxial growth layer; and
a step of performing dicing to provide each unit.

15. A method for manufacturing a semiconductor device comprising:
a step of preparing the epitaxial substrate according to claim 7;
a step of forming a functional layer made of a nitride semiconductor on the epitaxial growth layer; and
a step of performing dicing to provide each unit.

16. A method for manufacturing a semiconductor device comprising:
a step of preparing the epitaxial substrate according to claim 8;
a step of forming a functional layer made of a nitride semiconductor on the epitaxial growth layer; and
a step of performing dicing to provide each unit.

17. A method for manufacturing a semiconductor device comprising:
a step of preparing the epitaxial substrate according to claim 9;
a step of forming a functional layer made of a nitride semiconductor on the epitaxial growth layer; and
a step of performing dicing to provide each unit.
